(19) United States
(12) Patent Application Publication
(10) Pub. No.: US 2026/0005002 A1
(43) Pub. Date: Jan. 1, 2026

(54) SUBSTRATE PROCESSING APPARATUS

(71) Applicant: Samsung Electronics Co., Ltd., Suwon-si (KR)

(72) Inventors: Ji Mo Lee, Suwon-si (KR); Hyeong Mo Kang, Suwon-si (KR); Kyung-Sun Kim, Suwon-si (KR); Nam Kyun Kim, Suwon-si (KR); Yi Rop Kim, Suwon-si (KR); Hyuk Kim, Suwon-si (KR); Dong Hyeon Na, Suwon-si (KR); Yun A Lee, Suwon-si (KR); Hee Won Min, Suwon-si (KR); Kyoung Soo Chung, Suwon-si (KR)

(21) Appl. No.: 19/184,387

(22) Filed: Apr. 21, 2025

(30) Foreign Application Priority Data
Jun. 26, 2024 (KR) 10-2024-0083721

(51) Int. Cl. H01J 37/32

(52) U.S. Cl. CPC H01J 37/32669; H01J 2237/152

(57) ABSTRACT

A substrate processing apparatus includes: a chamber configured to process a substrate; a first electrode configured to form plasma in an internal space of the chamber; a second electrode facing the first electrode and configured to form plasma in the internal space of the chamber; and a magnetic body to control the plasma formed in the internal space of the chamber. The magnetic body includes a magnetic field generator, an electrode structure, and a mimic structure. The magnetic field generator includes a coil formed by stacked turns of a wire having two ends. The electrode structure is formed by both ends of the wire. The mimic structure is attached to the magnetic field generator and spaced apart from the electrode structure. The electrode structure has a length and the mimic structure has a length substantially the same as the length of the electrode structure.

### CROSS-REFERENCE TO RELATED APPLICATION

This application claims priority under 35 U.S.C. 119 from Korean Patent Application No. 10-2024-0083721, filed in the Korean Intellectual Property Office on Jun. 26, 2024, the disclosure of which is incorporated herein in its entirety.

### FIELD

The present disclosure relates to substrate processing apparatus.

### BACKGROUND

When manufacturing semiconductor devices or display devices, various processes such as etching, ashing, ion implantation, thin film deposition, and cleaning are conducted. Plasma can be utilized in these various processes.

Meanwhile, due to pattern miniaturization and other factors, precise plasma control is required. For example, direct-current signals or the like can be provided to electrodes in the processing chamber to uniformly form the dispersion of plasma on substrates.

### SUMMARY

Aspects of the present disclosure provide a substrate processing apparatus with improved process characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments, a substrate processing apparatus includes: a chamber configured to process a substrate; a first electrode configured to form plasma in an internal space of the chamber; a second electrode facing the first electrode and configured to form plasma in the internal space of the chamber; and a magnetic body to control the plasma formed in the internal space of the chamber. The magnetic body includes a magnetic field generator, an electrode structure, and a mimic structure. The magnetic field generator includes a coil formed by stacked turns of a wire, the wire having two ends. The electrode structure is formed by both ends of the wire. The mimic structure is attached to the magnetic field generator and spaced apart from the electrode structure. The electrode structure has a length, the mimic structure has a length, and the length of the mimic structure is substantially the same as the length of the electrode structure.

According to some embodiments, a substrate processing apparatus includes: a chamber configured to process a substrate; a first electrode configured to form plasma in an internal space of the chamber; a second electrode facing the first electrode and configured to form plasma in the internal space of the chamber; a first magnetic body to control the plasma formed in the internal space of the chamber; and a second magnetic body. The first magnetic body includes: a first magnetic field generator including a first coil formed by stacked turns of a first wire, the first wire having two ends; a first electrode structure, which is formed by both ends of the first wire; and a first mimic structure attached to the first magnetic field generator and spaced apart from the first electrode structure. The second magnetic body is located opposite the first magnetic body. The second magnetic body includes: a second magnetic field generator including a second coil formed by stacked turns of a second wire, the second wire having two ends; a second electrode structure, which is formed by both ends of the second wire; and a second coating layer surrounding the second magnetic field generator and the second structure. The first electrode structure has a length, the first mimic structure has a length, and the length of the first mimic structure is substantially the same as the length of the first electrode structure. The first magnetic body has a diameter, the second magnetic body has a diameter, and the diameter of the first magnetic body is substantially the same as the diameter of the second magnetic body.

According to some embodiments, a substrate processing apparatus includes: a chamber configured to process a substrate; a first electrode configured to form plasma in an internal space of the chamber; a second electrode facing the first electrode and configured to form plasma in the internal space of the chamber; a first magnetic body to control the plasma formed in the internal space of the chamber; and a second magnetic body. The first magnetic body is located inside the chamber. The first magnetic body includes: a first magnetic field generator including a coil formed by stacking turns of a first wire, the first wire having two ends; a first electrode structure, which is formed by both ends of the first wire; and a first mimic structure attached to the first magnetic field generator and being spaced apart from the first electrode structure. The second magnetic body is located opposite the first magnetic body. The second magnetic body includes: a second magnetic field generator including a coil formed by stacking turns of a second wire, the second wire having two ends; a second structure, which is formed by both ends of the second wire; and a second mimic structure attached to the second magnetic field generator and being spaced apart from the second electrode structure. The first magnetic body has a diameter, the second magnetic body has a diameter, and the diameter of the first magnetic body is substantially the same as the diameter of the second magnetic body. The first and second magnetic bodies receive current from first and second power sources, respectively. The first electrode structure and the first mimic structure form an angle of about 180 degrees therebetween about a center of the first magnetic body. The second electrode structure and the second mimic structure form an angle of about 180 degrees therebetween about a center of the second magnetic body. The first magnetic body is connected to a frequency filter that controls noise.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a drawing illustrating a substrate processing system according to some embodiments.

FIGS. 2 and 3 are diagrams illustrating substrate processing apparatuses included in the substrate processing system of FIG. 1 according to some embodiments.

FIG. 4 is a diagram illustrating the magnetic bodies included in the substrate processing apparatus of FIG. 2.

FIGS. 5 and 6 are cross-sectional views illustrating the magnetic bodies included in the substrate processing apparatus of FIG. 2.

FIGS. 7 and 8 are diagrams illustrating the magnetic field regions formed by the magnetic

bodies of FIG. 2.

FIG. 9 is a perspective view of a magnetic body of FIG. 2 according to some embodiments with mimic structures attached.

FIG. 10 is a perspective view of a sub-magnetic body and mimic structures included in the magnetic body of FIG. 9.

FIG. 11 is a circuit diagram illustrating the sub-magnetic body and mimic structures of FIG. 10.

FIG. 12 is a perspective view of a sub-magnetic body and mimic structures that may be included in a magnetic body according to further embodiments.

FIG. 13 is a circuit diagram illustrating the sub-magnetic body and mimic structures of FIG. 12.

FIG. 14 is a perspective view of a sub-magnetic body and mimic structures which may be included in a magnetic body according to further embodiments.

FIGS. 15 and 16 are diagrams illustrating substrate processing apparatuses that may be included in the substrate processing system of FIG. 1 in accordance with further embodiments.

### DETAILED DESCRIPTION

Embodiments of the present disclosure will hereinafter be described in detail with reference to the accompanying drawings. The same reference numerals are used for the same components in the drawings, and redundant explanations thereof will be omitted.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

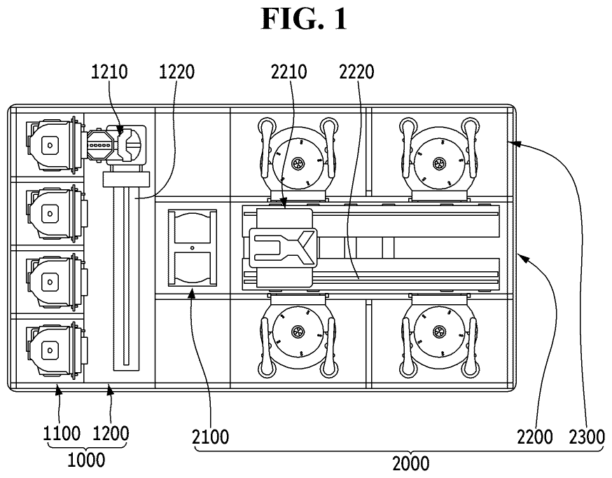

FIG. 1 is a drawing illustrating a substrate processing system according to some embodiments.

Referring to FIG. 1, the substrate processing system may include an index module 1000 and a processing module 2000.

The index module 1000 receives substrates from the outside and transfers the substrates to the processing module 2000. The processing module 2000 may perform at least one of cleaning, deposition, etching, and ashing processes. The index module 1000 may be an equipment front end module (EFEM). The index module 1000 may include load ports 1100 and a transfer frame 1200.

The load ports 1100 may accommodate substrates. Substrates may be placed in containers within the load ports 1100. The containers may be front opening unified pods (FOUPs). The container may be brought into the load ports 1100 from the outside by an overhead transfer (OHT). The containers may also be taken out of the load ports 1100 to the outside by the OHT. The transfer frame 1200 may transfer substrates between the load ports 1100 and the processing module 2000.

The processing module 2000 may be a module that actually performs processing. The processing module 2000 may include a buffer chamber 2100, a transfer chamber 2200, and processing chambers 2300. In some embodiments, each of the processing chambers 2300 may be in a tower form that includes multiple chambers, but the present disclosure is not limited thereto.

The buffer chamber 2100 may provide a space where substrates temporarily stay while being transferred between the index module 1000 and the processing module 2000. The buffer chamber 2100 may provide buffer slots where substrates are placed. A transfer robot 2210 in the transfer chamber 2200 may withdraw substrates placed in the buffer slots and transfer them to the processing chambers 2300. The buffer chamber 2100 may provide a plurality of buffer slots.

The transfer chamber 2200 may transfer substrates between the buffer chamber 2100 and the processing chambers 2300, which are arranged around the transfer chamber 2200. The transfer chamber 2200 may include the transfer robot 2210 and a transfer rail 2220. The transfer robot 2210 may transfer substrates while moving along the transfer rail 2220.

In some embodiments, the processing chambers 2300 may be substrate processing apparatuses. For example, at least one of cleaning, deposition, etching, and ashing processes may be performed in the processing chambers 2300. Specifically, an ashing process using plasma and/or radicals may be performed in the processing chambers 2300, but the present disclosure is not limited thereto.

Some of the processing chambers 2300 may be arranged on one side of the transfer chamber 2200. Some of the processing chambers 2300 may be arranged on the other side of the transfer chamber 2200. In other words, a plurality of processing chambers 2300 may be arranged to face each other on different sides of the transfer chamber 2200.

The processing module 2000 may be provided with a plurality of processing chambers 2300. The processing chambers 2300 may be arranged in a row on one side of the transfer chamber 2200, but the present disclosure is not limited thereto.

The arrangement of the processing chambers 2300 is not particularly limited, and may vary depending on the footprint or process efficiency of the substrate processing system.

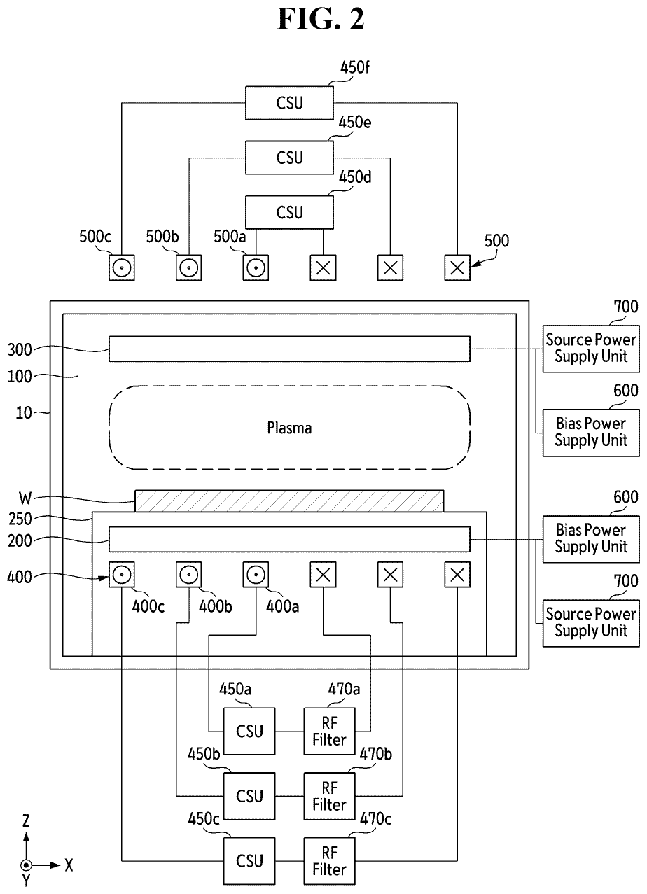

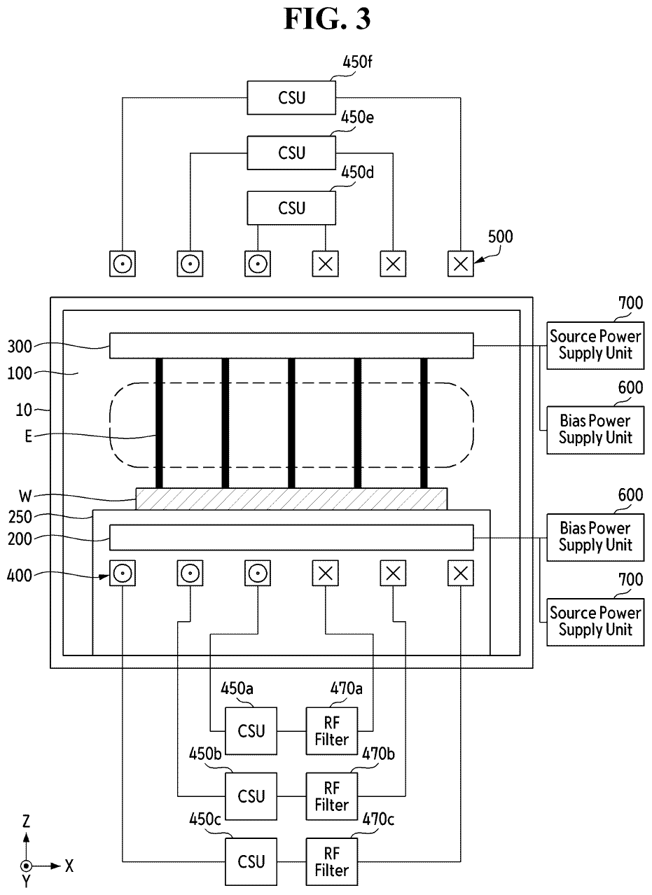

FIGS. 2 and 3 are diagrams illustrating substrate processing apparatuses according to some embodiments included in the substrate processing system of FIG. 1.

Referring to FIG. 2, a substrate processing apparatus according to some embodiments of the present disclosure may include a process chamber 10, a substrate support 250, a lower electrode 200, an upper electrode 300, an upper magnetic body 500, a lower magnetic body 400, current supply units 450a-d, frequency filters 470a-c, bias power supply units 600, and source power supply units 700.

The substrate processing apparatus may be a chamber for processing a substrate W using plasma and/or radicals. For example, in the substrate processing apparatus, a plasma process may be performed on the substrate W. For example, an etching process using plasma may be performed on the substrate W, but the present disclosure is not limited thereto. Alternatively, deposition, ashing, and cleaning processes may also be performed together within the substrate processing apparatus.

Here, the term “substrate” refers to the substrate itself or a laminated structure that includes the substrate and a predetermined layer or film formed on the surface of the substrate. Also, the term “surface of the substrate” refers to the exposed surface of the substrate itself or the exposed surface of the predetermined certain layer or film formed on the substrate. For example, the substrate may be a wafer, or may include a wafer and at least one material layer on the wafer. This material layer may be an insulating layer and/or a conductive layer formed on the wafer through various methods such as deposition or coating. For example, the insulating layer may include an oxide layer, a nitride layer, or an oxynitride layer, and the conductive layer may include a metal layer or a polysilicon layer. Additionally, the material layer may be a single layer or a multilayer and may be formed on the wafer with a predetermined pattern.

The process chamber 10 may form an internal space 100. The substrate W may be processed within the internal space 100 of the process chamber 10. Plasma may be formed in the internal space 100 of the process chamber 10.

The overall outer structure of the process chamber 10 may be in the form of a cylinder, an elliptical cylinder, or a polygonal column. The process chamber 10 is generally formed of a metal and may maintain an electrical ground state to block noise from the outside during the plasma process.

Although not illustrated, the inside of the process chamber 10 may be provided with a liner. The liner may protect the process chamber 10 and may cover the metal structures within the process chamber 10 to prevent metal contamination caused by arcing inside. The liner may be formed of a metal material such as aluminum or a ceramic material. Additionally, the liner may be formed of a material film that is resistant to plasma. For example, the material film resistant to plasma may be a yttrium oxide (Y₂O₃) film, but the present disclosure is not limited thereto.

Although not illustrated, a shower head may be arranged within the process chamber 10. The shower head may include a plurality of holes and may inject plasma through these holes.

The substrate support 250 may be disposed below the process chamber 10. The substrate support 250 may support the substrate W.

The substrate support 250 may be an electrostatic chuck configured to support the substrate W using electrostatic force. The electrostatic chuck may include an electrode inside for chucking and dechucking the substrate W. The chuck support supports the electrostatic chuck disposed on top and may be formed of a metal such as aluminum or a ceramic insulator such as alumina. A heating member such as a heater may be disposed inside the chuck support, allowing heat to be transferred from the heater to the electrostatic chuck or the substrate W. Additionally, power wiring, which is connected to the electrode of the electrostatic chuck, may be disposed in the chuck support. The configuration of the substrate support 250 is not particularly limited, and the substrate support 250 may include a vacuum chuck configured to support the substrate W using vacuum or a mechanical chuck configured to mechanically support the substrate W.

The lower electrode 200 may be disposed inside the substrate support 250, but the present disclosure is not limited thereto. For example, the lower electrode 200 may be disposed below the substrate support 250. The lower electrode 200 may be connected to the source power supply unit 700 and/or the bias power supply unit 600. The lower electrode 200 may receive power signals from the source power supply unit 700 and/or the bias power supply unit 600.

The upper electrode 300 may be disposed at an upper part of the process chamber 10. The upper electrode 300 may be disposed above the substrate support 250. The upper electrode 300 may be connected to the source power supply unit 700 and/or the bias power supply unit 600. The upper electrode 300 may receive power signals from the source power supply unit 700 and/or the bias power supply unit 600.

The lower magnetic body 400 may be disposed below the lower electrode 200. The lower magnetic body 400 may be disposed inside the process chamber 10. The lower magnetic body 400 may be connected to the current supply units (CSU) 450a-c. The lower magnetic body 400 may receive current from the current supply units 450a-c, thereby forming a magnetic field. The lower magnetic body 400 may be connected to the frequency filters 470a-c. The lower magnetic body 400 may control noise generated in the lower magnetic body 400 through the frequency filters 470a-c.

The lower magnetic body 400 may include a plurality of sub-magnetic bodies. The lower magnetic body 400 may include a first sub-magnetic body 400a, a second sub-magnetic body 400b, and a third sub-magnetic body 400c. The first, second, and third sub-magnetic bodies 400a, 400b, and 400c may be connected to first, second, and third current supply units (CSU) 450a, 450b, and 450c, respectively, and first, second, and third frequency filters 470a, 470b, and 470c, respectively. Therefore, the current signals flowing through the first, second, and third sub-magnetic bodies 400a, 400b, and 400c can be controlled individually (i.e., independently of one another).

The upper magnetic body 500 may be disposed above the upper electrode 300. The upper magnetic body 500 may be disposed outside the process chamber 10. The upper magnetic body 500 may be connected to the current supply units 450d-f. The upper magnetic body 500 may receive current from the current supply unit 450, thereby forming a magnetic field.

The upper magnetic body 500 may include a plurality of sub-magnetic bodies. The upper magnetic body 500 may include a fourth sub-magnetic body 500a, a fifth sub-magnetic body 500b, and a sixth sub-magnetic body 500c. The fourth, fifth, and sixth sub-magnetic bodies 500a, 500b, and 500c may be connected to current supply units 450d, 450c, and 450f, respectively. Therefore, the current signals flowing through the fourth, fifth, and sixth sub-magnetic bodies 500a, 500b, and 500c can be controlled individually (i.e., independently of one another).

The lower and upper magnetic bodies 400 and 500 may be formed as electromagnets or permanent magnets.

The bias power supply unit 600 may provide a bias power signal to the lower electrode 200. The bias power signal provided to the lower electrode 200 may be a pulse-type alternating current (AC) or direct current (DC) signal. For example, the bias power signal may include a radio frequency (RF) power signal.

The source power supply unit 700 may provide a source power signal to the upper electrode 300. The source power signal provided to the upper electrode 300 may be a pulse-type DC or AC signal.

Referring to FIG. 3, an electric field E may be formed between the bias power electrode 200 and the source power electrode 300. The electric field E may be formed in parallel to a Z-axis direction. A magnetic field may be formed between the bias power electrode 200 and the source power electrode 300. The magnetic field may have a component in the Z-axis direction and a component in an X-and Y-axis direction.

To simplify the analysis and control of the magnetic field, at least one pair of magnetic bodies facing each other may be formed inside or outside the process chamber 10. This can ensure a uniform plasma density. The shapes of the upper magnetic body 500 and the lower magnetic body 400 will be described later.

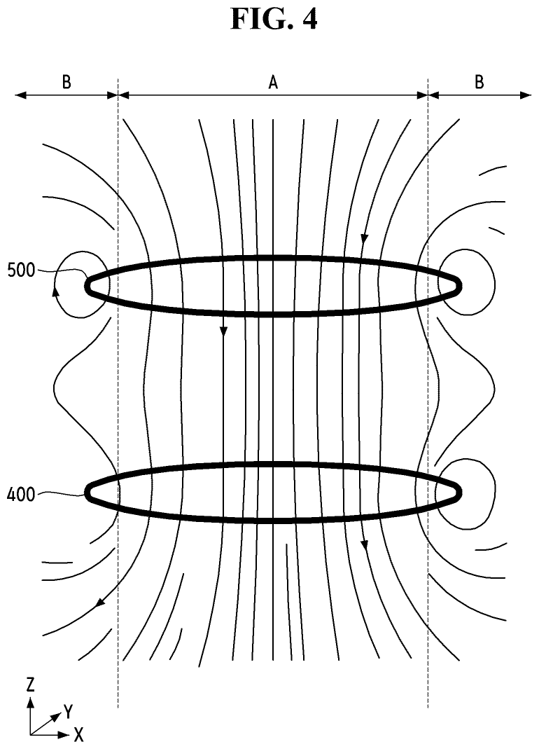

FIG. 4 is a diagram illustrating the magnetic bodies included in the substrate processing apparatus of FIG. 2.

Referring to FIG. 4, a magnetic field may be formed by a pair of opposing magnetic bodies.

In some embodiments, the magnetic field formed by the upper magnetic body 500 and the lower magnetic body 400 may have different shapes depending on the region. For example, the magnetic field formed by the upper magnetic body 500 and the lower magnetic body 400 may have a component in the Z-axis direction and a component in the X-and Y-axis direction.

In some embodiments, the magnetic field formed by a pair of magnetic bodies in their overlapping area (e.g., a first magnetic field region A) may have only a component in the Z-axis direction. For example, the magnetic field region formed by the upper magnetic body 500 and the lower magnetic body 400 may include the first magnetic field region A and a second magnetic field region B. The magnetic field formed in the first magnetic field region A may have only a component in the Z-axis direction. That is, the analysis and control of the magnetic field can be simplified. Accordingly, plasma can be uniformly formed.

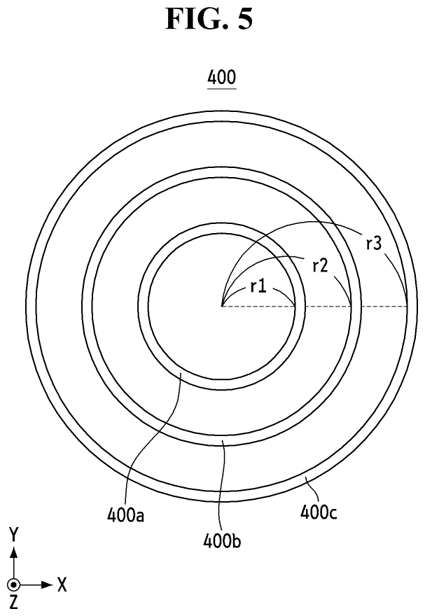

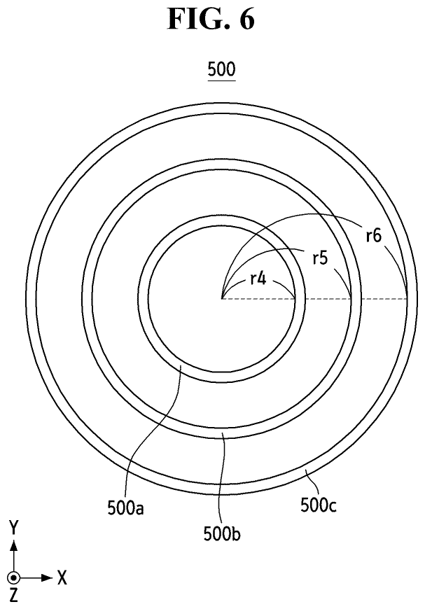

FIGS. 5 and 6 are cross-sectional views illustrating the magnetic bodies included in the substrate processing apparatus of FIG. 2.

Referring to FIG. 5, the lower magnetic body 400 may include a plurality of sub-magnetic bodies. The lower magnetic body 400 may include the first, second, and third sub-magnetic bodies 400a, 400b, and 400c.

The first sub-magnetic body 400a may have a first diameter r1. The second sub-magnetic body 400b may have a second diameter r2. The third sub-magnetic body 400c may have a third diameter r3.

The lower magnetic body 400 is illustrated as including three sub-magnetic bodies, but the present disclosure is not limited thereto.

The current signals flowing through the first, second, and third sub-magnetic bodies 400a, 400b, and 400c can be controlled individually.

Referring to FIG. 6, the upper magnetic body 500 may include a plurality of sub-magnetic bodies. The upper magnetic body 500 may include the fourth, fifth, and sixth sub-magnetic bodies 500a, 500b, and 500c.

The fourth sub-magnetic body 500a may have a fourth diameter r4. The fifth sub-magnetic body 500b may have a fifth diameter r5. The sixth sub-magnetic body 500c may have a sixth diameter r6.

The upper magnetic body 500 is illustrated as including three sub-magnetic bodies, but the present disclosure is not limited thereto.

The current signals flowing through the fourth, fifth, and sixth sub-magnetic bodies 500a, 500b, and 500c can be controlled individually.

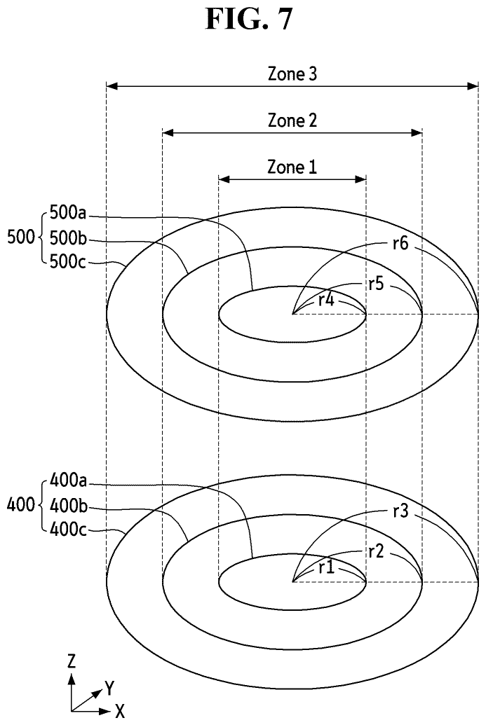

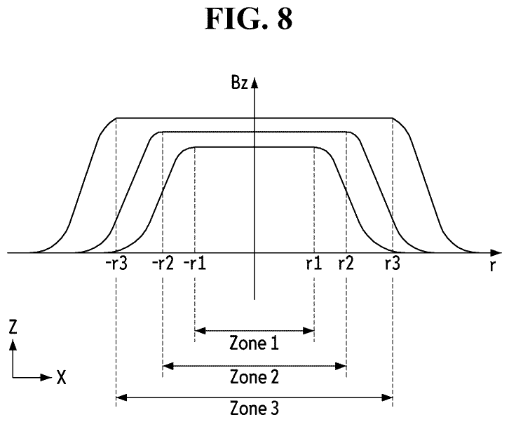

FIGS. 7 and 8 are diagrams illustrating the magnetic field regions formed by the magnetic bodies 400, 500 of FIG. 2.

Referring to FIGS. 7 and 8, a magnetic field region may be formed by the lower magnetic body 400, which includes the first, second, and third sub-magnetic bodies 400a, 400b, and 400c, and the upper magnetic body 500, which includes the fourth, fifth, and sixth sub-magnetic bodies 500a, 500b, and 500c.

The lower and upper magnetic bodies 400 and 500 may overlap in the Z-axis direction. For example, the first and fourth sub-magnetic bodies 400a and 500a may overlap in the Z-axis direction. The second and fifth sub-magnetic bodies 400b and 500b may overlap in the Z-axis direction. The third and sixth sub-magnetic bodies 400c and 500c may overlap in the Z-axis direction.

The first sub-magnetic body 400a may have the first diameter r1. The second sub-magnetic body 400b may have the second diameter r2. The third sub-magnetic body 400c may have the third diameter r3. The fourth sub-magnetic body 500a may have the fourth diameter r4. The fifth sub-magnetic body 500b may have the fifth diameter r5. The sixth sub-magnetic body 500c may have the sixth diameter r6.

The first and fourth diameters r1 and r4 may be the same. Accordingly, as described with reference to FIG. 4, a first zone Zone1 (FIG. 7) having only a component in the Z-axis direction may be formed between the first and fourth sub-magnetic bodies 400a and 500a. The second and fifth diameters r2 and r5 may be the same. Accordingly, as described with reference to FIG. 4, a second zone Zone2 having only a component in the Z-axis direction may be formed between the second and fifth sub-magnetic bodies 400b and 500b. The third and sixth diameters r3 and r6 may be the same. Accordingly, as described with reference to FIG. 4, a third zone Zone3 having only a component in the Z-axis direction may be formed between the third and sixth sub-magnetic bodies 400c and 500c.

Referring to FIG. 8, zones where a uniform magnetic field is formed by the lower and upper magnetic bodies 400 and 500 of FIG. 7 may be formed. The X-axis represents the diameter of the lower and upper magnetic bodies 400 and 500, and the Y-axis represents the magnitude of the magnetic field in the Z-axis direction.

The size of the zones where a uniform magnetic field is formed may vary depending on the diameter of the lower and upper magnetic bodies 400 and 500. For example, the first zone Zone1 may be formed between the first and fourth sub-magnetic bodies 400a and 500a having the same diameter (e.g., the first diameter r1), and a uniform magnetic field may be formed in the first zone Zone1, which ranges between −r1 and r1. The second zone Zone2 may be formed between the second and fifth sub-magnetic bodies 400b and 500b having the same diameter (e.g., the second diameter r2), and a uniform magnetic field may be formed in the second zone Zone2, which ranges between −r2 and r2. The third zone Zone3 may be formed between the third and sixth sub-magnetic bodies 400c and 500c having the same diameter (e.g., the third diameter r3), and a uniform magnetic field may be formed in the third zone Zone3, which ranges between −r3 and r3.

In some embodiments, for uniform processing across the entire substrate W, the diameter of the upper magnetic body 500 and the lower magnetic body 400 may be greater than the diameter of the substrate W. That is, any one of the first, second, and third sub-magnetic bodies 400a, 400b, and 400c may have a greater diameter than the substrate W. Accordingly, the analysis and control of a magnetic field can be simplified, allowing the density of plasma to be uniformly controlled.

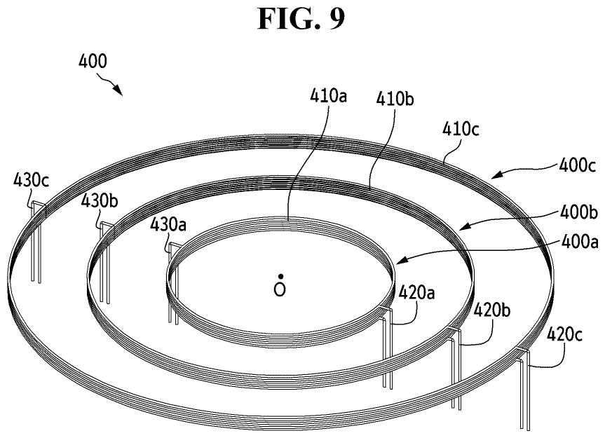

The magnitude of the magnetic field may increase from the first zone Zone1 to the second zone Zone2 to the third zone Zone3, but the present disclosure is not limited thereto. The magnitude of the magnetic field may vary depending on the current supplied to each sub-magnetic body or the number of turns in the coils forming first, second, and third magnetic field generators 410a, 410b, and 410c of FIG. 9.

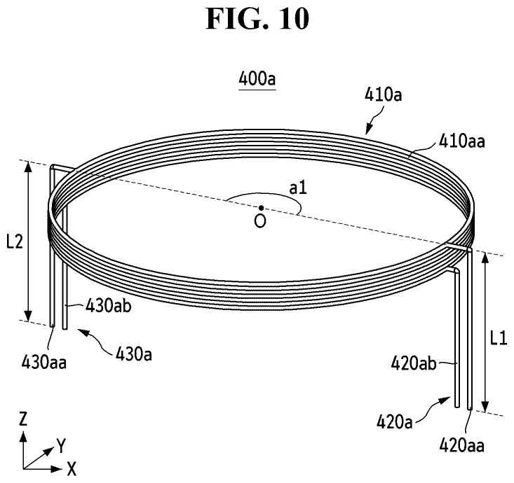

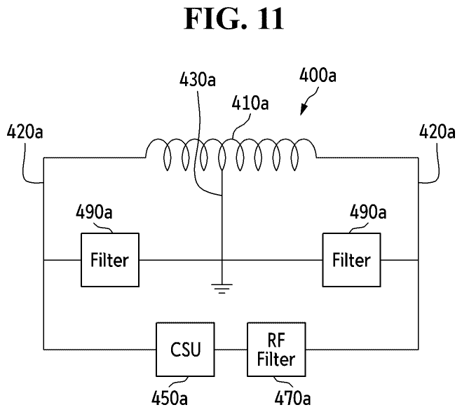

FIG. 9 is a diagram for explaining an example magnetic body of FIG. 2 with mimic structures attached. FIG. 10 is a diagram for explaining an example sub-magnetic body and mimic structures included in the magnetic body of FIG. 9. FIG. 11 is a circuit diagram illustrating the sub-magnetic body and mimic structures of FIG. 10. FIGS. 9 through 11 illustrate only a lower magnetic body 400, but the explanations for the lower magnetic body 400 may also be applicable to an upper magnetic body 500. Additionally, FIGS. 10 and 11 illustrate only a first sub-magnetic body 400a, but the explanations for the first sub-magnetic body 400a may also be applicable to second and third sub-magnetic bodies 400b and 400c of the lower magnetic body 400 and fourth, fifth, and sixth sub-magnetic bodies 500a, 500b, and 500c of the upper magnetic body 500.

Referring to FIGS. 2 and 9 through 11, the lower magnetic body 400 may be disposed below the lower electrode 200. The lower magnetic body 400 may be disposed inside the process chamber 10. The lower magnetic body 400 may include a plurality of sub-magnetic bodies. The lower magnetic body 400 may include the first, second, and third sub-magnetic bodies 400a, 400b, and 400c.

The lower magnetic body 400 may be in the form of a solenoid obtained by winding wires into coil shapes. The first sub-magnetic body 400a included in the lower magnetic body 400 may include a first magnetic field generator 410a, which is formed by stacking turns of a wire 410aa into a coil, and a first structure 420a, which is formed by electrodes 420aa and 420ab at both ends of the wire 410aa. The electrodes 420aa and 420ab may be formed from each respective end of the wire 410aa. The second sub-magnetic body 400b may include a second magnetic field generator 410b, which is formed by stacking turns of a wire 410ba into a coil, and a second structure 420b, which is formed by electrodes located at both ends of the wire 410ba. The electrodes of the second structure 420b may be formed from each respective end of the wire 410ba forming the second magnetic field generator 410b. The third sub-magnetic body 400c may include a third magnetic field generator 410c, which is formed by stacking turns of a wire 410ca into a coil, and a third structure 420c, which is formed by electrodes at both ends of the wire 410ca. The electrodes of the third structure 420c may be formed from each respective end of the wire 410ca forming the third magnetic field generator 410c. The first, second, and third structures 420a, 420b, and 420c are each positioned off-center on the sides of the first, second, and third magnetic field generators 410a, 410b, and 410c, respectively, which may cause electromagnetic wave deflection and create a non-linear physical environment in the plasma, leading to asymmetrical processing results.

The first, second, and third structures 420a, 420b, and 420c may be referred to as electrode structures. The electrodes 420aa, 420ab, etc. of the electrode structures 420a, 420b, and 420c may operatively electrically connect each of the magnetic field generators 410a, 410b, 410c to the coil's respective CSU 450a, 450b, and 450c. For example, the electrode 420aa may be a current input electrode connected to the CSU 450a and the electrode 420ab may be a current output electrode.

The wires that form the first, second, and third magnetic field generators 410a, 410b, and 410c (e.g., the wire 410aa) and the first, second, and third structures 420a, 420b, and 420c may be electrically conductive. The wires that form the first, second, and third magnetic field generators 410a, 410b, and 410c and the first, second, and third structures 420a, 420b, and 420c may be formed of metal.

Therefore, in some embodiments, the first, second, and third sub-magnetic bodies 400a, 400b, and 400c may include first, second, and third mimic structures 430a, 430b, and 430c, respectively, which are positioned symmetrically to the first, second, and third structures 420a, 420b, and 420c, respectively. For example, the first mimic structure 430a may be positioned symmetrically to the first structure 420a with respect to a center O of the lower magnetic body 400. In some embodiments, the first mimic structure 430a is positioned diametrically opposite the first structure 420a with respect to a center O. That is, an angle al formed between the first structure 420a and the first mimic structure 430a with respect to the center O of the lower magnetic body 400 may be 180 degrees. The second mimic structure 430b may be positioned symmetrically to the second structure 420b with respect to the center O of the lower magnetic body 400. In some embodiments, the second mimic structure 430b is positioned diametrically opposite the second structure 420b with respect to a center O. That is, the angle formed between the second structure 420b and the second mimic structure 430b with respect to the center O of the lower magnetic body 400 may be 180 degrees. The third mimic structure 430c may be positioned symmetrically to or diametrically opposite the third structure 420c with respect to the center O of the lower magnetic body 400. In some embodiments, the third mimic structure 430c is positioned diametrically opposite the third structure 420c with respect to a center O. That is, the angle formed between the third structure 420c and the third mimic structure 430c with respect to the center O of the lower magnetic body 400 may be 180 degrees.

Additionally, the shape of the first mimic structure 430a may be substantially identical or similar to that of the first structure 420a. For example, the first structure 420a may have a first length L1, and the first mimic structure 430a may have a second length L2, which is substantially identical or similar to the first length L1. The first structure 420a may have the first length L1, and the first mimic structure 430a may have a second length L2, which is substantially identical or similar to the first length L1.

In some embodiments (e.g., as illustrated in FIGS. 9 and 10), the first mimic structure includes a first portion 430aa having substantially the same shape and size as the first electrode 420aa, and a second portion 430ab having substantially the same shape and size as the second electrode 420ab.

The first, second, and third mimic structures 430a, 430b, and 430c may be electrically conductive. The first, second, and third mimic structures 430a, 430b, and 430c may be formed of metal.

In some embodiments, the first, second, and third mimic structures 430a, 430b, and 430c may be directly connected to the first, second, and third magnetic field generators 410a, 410b, and 410c, respectively. Additionally, the first, second, and third mimic structures 430a, 430b, and 430c may be connected to the electrical ground.

By attaching the first, second, and third mimic structures 430a, 430b, and 430c to the first, second, and third sub-magnetic bodies 400a, 400b, and 400c, respectively, the deflection of electromagnetic waves can be prevented, and the processing results can become uniform.

Additionally, the lower magnetic body 400 may be connected to the current supply units 450a-c. The lower magnetic body 400 may receive current from the current supply units 450a-c, thereby forming a magnetic field. The lower magnetic body 400 may be connected to the frequency filters 470a-c. The lower magnetic body 400 may control noise generated in the lower magnetic body 400 through the frequency filters 470a-c.

The first, second, and third sub-magnetic bodies 400a, 400b, and 400c may be connected to the first, second, and third current supply units 450a, 450b, and 450c, respectively, and the first, second, and third frequency filters 470a, 470b, and 470c, respectively. Therefore, the current signals flowing through the first, second, and third sub-magnetic bodies 400a, 400b, and 400c can be controlled individually.

In some embodiments, if the first, second, and third mimic structures 430a, 430b, and 430c are directly connected to the first, second, and third magnetic field generators 410a, 410b, and 410c, respectively, filters 490a, 490b and 490c may be connected between the first structure 420a and the first mimic structure 430a, between the second structure 420b and the second mimic structure 430b and between the third structure 420c and the third mimic structure 430c, second, and third structures 420a, 420b, and 420c and the first, second, and third mimic structures 430a, 430b, and 430c. For example, the first filter 490a connected between the first structure 420a and the first mimic structure 430a may eliminate noise by removing the DC component of a first signal or controlling the signal of a particular frequency.

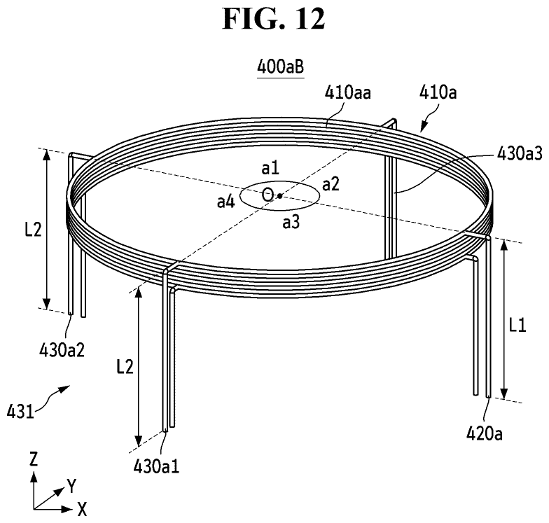

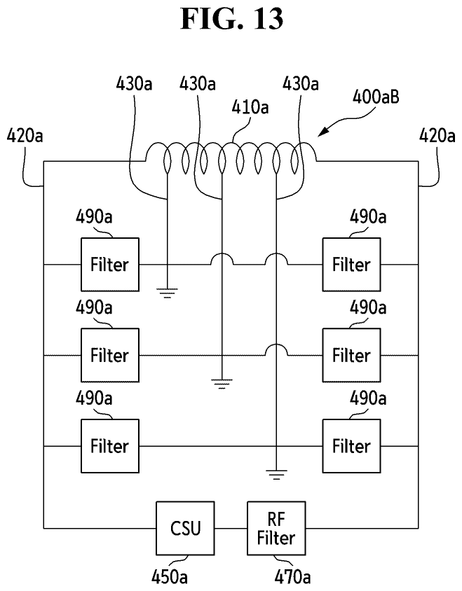

FIG. 12 is a diagram for explaining sub-magnetic body and mimic structures included in the magnetic body in accordance with further embodiments. FIG. 13 is a circuit diagram illustrating the sub-magnetic body and mimic structures of FIG. 12. Reference numerals used herein and labeled in FIGS. 1-11 to describe the substrate processing system and magnetic bodies thereof are also used herein and labeled in FIGS. 12 and 13 to designate similar or corresponding components and features of the substrate processing system and magnetic bodies of FIGS. 12 and 13.

Referring to FIGS. 12 and 13, in some embodiments, a first sub-magnetic body 400a may include a plurality or set 431 of first mimic structures, which are positioned symmetrically to a first structure 420a. For example, the first mimic structures set 431 may include a first sub-mimic structure 430a1, a second sub-mimic structure 430a2, and a third sub-mimic structure 430a3. The first structure 420a and the first sub-mimic structures 430a1, 430a2, 430a3 may be positioned or spaced apart at equal angles around the center O of the lower magnetic body 400. That is, angles a1, a2, a3, and a4 formed between the first structure 420a, the first sub-mimic structure 430a1, the second sub-mimic structure 430a2, and the third sub-mimic structure 430a3 with respect to or about the center O of the lower magnetic body 400 may all be 90 degrees (i.e., the angles between adjacent pairs of the structures 420a, 430a1, 430a2, and 430a3).

Additionally, the shape of the first sub-mimic structures 430a1, 430a2, 430a3 may be substantially identical or similar to that of the first structure 420a. For example, the first structure 420a may have a first length L1, and the first sub-mimic structures 430a1, 430a2, 430a3 may have a second length L2, which is substantially identical or similar to the first length L1. That is, the first, second, and third sub-mimic structures 430a may all have a second length L2 that is identical to the first length L1.

In some embodiments, the first, second, and third sub-mimic structures 430a1, 430a2, 430a3 may be directly connected to a first magnetic field generator 410a. Additionally, the first, second, and third sub-mimic structures 430a1, 430a2, 430a3 may be connected to the electrical ground. By attaching the first, second, and third sub-mimic structures 430a1, 430a2, 430a3 to the first sub-magnetic body 400a, the deflection of electromagnetic waves can be prevented, and the processing results can become uniform.

Additionally, the first sub-magnetic body 400a may be connected to a current supply unit 450a. The first sub-magnetic body 400a may receive current from the current supply unit 450a, thereby forming a magnetic field. The first sub-magnetic body 400a may be connected to a frequency filter 470a. The first sub-magnetic body 400a may control noise generated in the first sub-magnetic body 400a through the frequency filter 470a.

In some embodiments, if the first, second, and third sub-mimic structures 430a1, 430a2, 430a3 are directly connected to the first magnetic field generator 410a, filters 490a may be connected between the first structure 420a and the first, second, and third sub-mimic structures 430a1, 430a2, 430a3. For example, the filter 490a connected between the first structure 420a and the first sub-mimic structure 430a may eliminate noise by removing the DC component of a first signal or controlling the signal of a particular frequency.

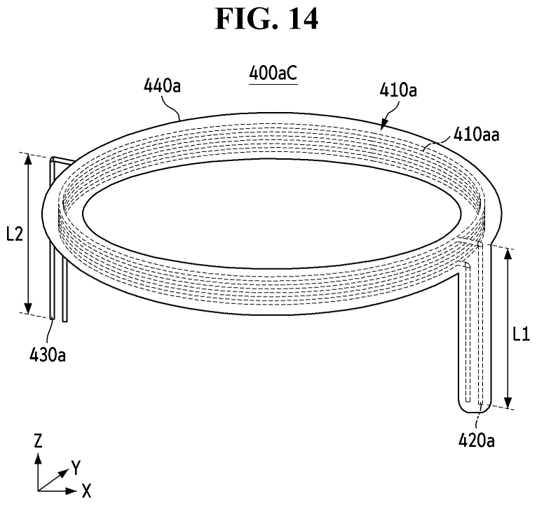

FIG. 14 is a diagram for explaining another sub-magnetic body and mimic structures included in the magnetic body according to further embodiments. The configuration illustrated in FIG. 14 will hereinafter be described, focusing mainly on the differences from the configuration illustrated in FIG. 10. Reference numerals used herein and labeled in FIGS. 1-11 to describe the substrate processing system and magnetic bodies thereof are also used herein and labeled in FIG. 14 to designate similar or corresponding components and features of the sub-magnetic body of FIG. 14.

Referring to FIG. 14, in some embodiments, a first sub-magnetic body 400a may include a first mimic structure 430a, which is positioned symmetrically to or diametrically opposite a first structure 420a.

Additionally, the shape of the first mimic structure 430a may be substantially identical or similar to that of the first structure 420a. For example, the first structure 420a may have a first length LI, and the first mimic structure 430a may have a second length L2, which is identical or similar to the first length L1.

In some embodiments, the first mimic structure 430a may not be directly connected to a first magnetic field generator 410a. For example, the first mimic structure 430a may be attached to a coating layer 440a that surrounds the first magnetic field generator 410a and the first structure 420a. Additionally, the first mimic structure 430a may be connected to the electrical ground.

By attaching the first mimic structure 430a, a second mimic structure 430b, and a third mimic structure 430c to the first sub-magnetic body 400a, a second sub-magnetic body 400b, and a third sub-magnetic body 400c, respectively, the deflection of electromagnetic waves can be prevented, and the processing results can become uniform.

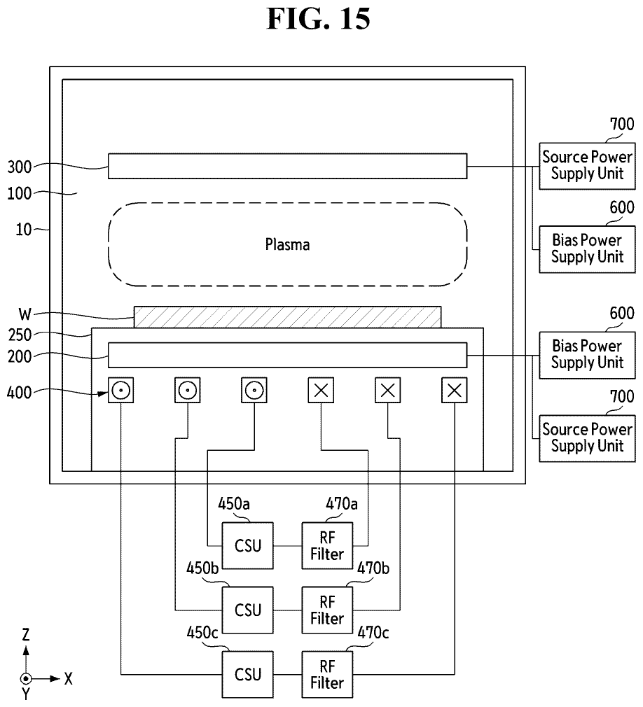

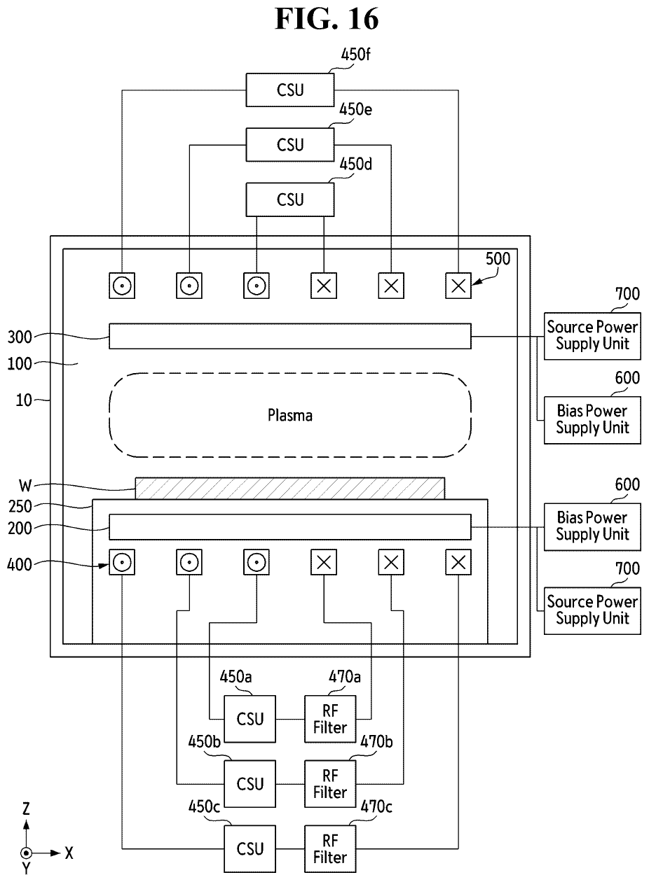

FIGS. 15 and 16 are diagrams illustrating example substrate processing apparatuses included in the substrate processing system of FIG. 1. The configurations illustrated in FIGS. 15 and 16 will hereinafter be described, focusing mainly on the differences from the configuration illustrated in FIG. 1. Reference numerals used herein and labeled in FIGS. 1-11 to describe the substrate processing system and magnetic bodies thereof are also used herein and labeled in FIGS. 15 and 16 to designate similar or corresponding components and features of the substrate processing system and magnetic bodies of FIGS. 15 and 16.

Referring to FIG. 15, a substrate processing apparatus according to some embodiments of the present disclosure may include a process chamber 10, a substrate support 250, a lower electrode 200, an upper electrode 300, a lower magnetic body 400, a current supply unit 450, a frequency filter 470, a bias power supply unit 600, and a source power supply unit 700. That is, the substrate processing apparatus may not include the upper magnetic body 500 of FIG. 2.

The lower magnetic body 400 may be disposed below the lower electrode 200. The lower magnetic body 400 may be disposed inside the process chamber 10. The lower magnetic body 400 may be connected to the current supply unit 450. The lower magnetic body 400 may receive current from the current supply unit 450, thereby forming a magnetic field. The lower magnetic body 400 may be connected to the frequency filter 470. The lower magnetic body 400 may control noise generated in the lower magnetic body 400 through the frequency filter 470.

The lower magnetic body 400, like its counterpart of FIG. 9 or FIG. 14, may include first, second, and third mimic structures 430a, 430b, and 430c. This can prevent the deflection of electromagnetic waves and result in uniform processing results.

Referring to FIG. 16, a substrate processing apparatus according to some embodiments of the present disclosure may include a process chamber 10, a substrate support 250, a lower electrode 200, an upper electrode 300, a lower magnetic body 400, an upper magnetic body 500, a current supply unit 450, a frequency filter 470, a bias power supply unit 600, and a source power supply unit 700.

The lower magnetic body 400 may be disposed below the lower electrode 200. The lower magnetic body 400 may be disposed inside the process chamber 10. The lower magnetic body 400 may be connected to the current supply unit 450. The lower magnetic body 400 may receive current from the current supply unit 450, thereby forming a magnetic field. The lower magnetic body 400 may be connected to the frequency filter 470. The lower magnetic body 400 may control noise generated in the lower magnetic body 400 through the frequency filter 470.

The upper magnetic body 500 may be disposed above the upper electrode 300. The upper magnetic body 500 may be disposed inside the process chamber 10. The upper magnetic body 500 may be connected to the current supply unit 450. The upper magnetic body 500 may receive current from the current supply unit 450, thereby forming a magnetic field. Although not illustrated, a filter may be included between the upper magnetic body 500 and the current supply unit 450. This filter may be the same as the frequency filter 470 between the lower magnetic body 400 and the current supply unit 450.

Each of the lower and upper magnetic bodies 400 and 500 may include first, second, and third mimic structures 430a, 430b, and 430c, as described earlier with reference to FIGS. 9 and 14. This can prevent the deflection of electromagnetic waves and result in uniform processing results.

While example embodiments of the present disclosure have been described with reference to the accompanying drawings, the present disclosure is not limited to the above embodiments and may be manufactured in various different forms. Those skilled in the art to which the present disclosure pertains will understand that the present disclosure can be embodied in other specific forms without changing the technical spirit or essential features of the present disclosure. Therefore, it should be understood that the above-described embodiments are illustrative in all respects and not restrictive.

What is claimed is:

1. A substrate processing apparatus comprising:
a chamber configured to process a substrate;
a first electrode configured to form plasma in an internal space of the chamber;
a second electrode facing the first electrode and configured to form plasma in the internal space of the chamber; and
a magnetic body to control the plasma formed in the internal space of the chamber, the magnetic body including:
a magnetic field generator including a coil formed by stacked turns of a wire, the wire having two ends;
an electrode structure, which is formed by both ends of the wire; and
a mimic structure attached to the magnetic field generator and spaced apart from the electrode structure;
wherein the electrode structure has a length, the mimic structure has a length, and the length of the mimic structure is substantially the same as the length of the electrode structure.

2. The substrate processing apparatus of claim 1, wherein:
the mimic structure is a first sub-mimic structure;
the magnetic body includes a second sub-mimic structure; and
angles formed between the first sub-mimic structure, the second sub-mimic structure, and the electrode structure with respect to a center of the magnetic body are all substantially the same.

3. The substrate processing apparatus of claim 2, wherein:
the magnetic body includes a third sub-mimic structure; and
angles formed between the first, second, and third sub-mimic structures and the electrode structure with respect to the center of the magnetic body are all substantially the same.

4. The substrate processing apparatus of claim 1, further comprising:
a filter connected between the mimic structure and the electrode structure to control a signal between the mimic structure and the electrode structure,
wherein one end of the mimic structure is connected to an electrical ground.

5. The substrate processing apparatus of claim 1, wherein:
the magnetic body further includes a coating layer; and
the coating layer is disposed between the magnetic field generator and the mimic structure.

6. The substrate processing apparatus of claim 1, further comprising:
a second magnetic body different from the magnetic body.

7. The substrate processing apparatus of claim 6, wherein the second magnetic body is disposed outside the chamber.

8. The substrate processing apparatus of claim 6, wherein diameters of the magnetic body and the second magnetic body are substantially the same.

9. The substrate processing apparatus of claim 8, wherein:
the magnetic body includes a first sub-magnetic body, a second sub-magnetic body, and a third sub-magnetic body, and
the second magnetic body includes a fourth sub-magnetic body having substantially the same diameter as the first sub-magnetic body, a fifth sub-magnetic body having substantially the same diameter as the second sub-magnetic body, and a sixth sub-magnetic body having substantially the same diameter as the third sub-magnetic body.

10. The substrate processing apparatus of claim 9, wherein:
the diameter of the third sub-magnetic body is greater than the diameters of the first and second sub-magnetic bodies; and
the diameter of the third sub-magnetic body is greater than the diameter of the substrate.

11. The substrate processing apparatus of claim 9, wherein the first, second, third, fourth, fifth, and sixth sub-magnetic bodies are connected to first, second, third, fourth, fifth, and sixth power sources, respectively.

12. The substrate processing apparatus of claim 6, wherein:
the second magnetic body includes:
a second magnetic field generator including a second coil formed by stacked turns of a second wire, the second wire having two ends;
a second electrode structure, which is formed by both ends of the second wire;
a second coating layer, which surrounds the second magnetic field generator and the second electrode structure, and
a second mimic structure attached to the second magnetic field generator and spaced apart from the second electrode structure.

13. The substrate processing apparatus of claim 1, wherein the magnetic body is connected to a frequency filter that controls noise.

14. A substrate processing apparatus comprising:
a chamber configured to process a substrate;
a first electrode configured to form plasma in an internal space of the chamber;
a second electrode facing the first electrode and configured to form plasma in the internal space of the chamber;
a first magnetic body to control the plasma formed in the internal space of the chamber, the first magnetic body including:
a first magnetic field generator including a first coil formed by stacked turns of a first wire, the first wire having two ends;
a first electrode structure, which is formed by both ends of the first wire; and
a first mimic structure attached to the first magnetic field generator and spaced apart from the first electrode structure; and
a second magnetic body located opposite the first magnetic body, the second magnetic body including:
a second magnetic field generator including a second coil formed by stacked turns of a second wire, the second wire having two ends;
a second electrode structure, which is formed by both ends of the second wire; and
a second coating layer surrounding the second magnetic field generator and the second electrode structure;
wherein:
the first electrode structure has a length, the first mimic structure has a length, and the length of the first mimic structure is substantially the same as the length of the first electrode structure; and
the first magnetic body has a diameter, the second magnetic body has a diameter, and the diameter of the first magnetic body is substantially the same as the diameter of the second magnetic body.

15. The substrate processing apparatus of claim 14, wherein an angle formed between the first mimic structure and the first electrode structure is 180 degrees.

16. The substrate processing apparatus of claim 14, wherein:
the first mimic structure is a first sub-mimic structure, and the first magnetic body further includes a second sub-mimic structure and a third sub-mimic structure; and
angles formed between the first sub-mimic structure, the second sub-mimic structure, the third sub-mimic structure and the first electrode structure with respect to a center of the first magnetic body are each 90 degrees.

17. The substrate processing apparatus of claim 14, wherein:
one end of the first mimic structure is connected to an electrical ground; and
the substrate processing apparatus further comprises a filter connected between the first mimic structure and the first electrode structure to control signals between the first mimic structure and the first electrode structure.

18. The substrate processing apparatus of claim 14, wherein:
the first magnetic body includes a first sub-magnetic body, a second sub-magnetic body, and a third sub-magnetic body, each having a respective diameter;
the second magnetic body includes a fourth sub-magnetic body having a diameter that is substantially the same as the diameter of the first sub-magnetic body, a fifth sub-magnetic body having a diameter that is substantially the same as the diameter of the second sub-magnetic body, and a sixth sub-magnetic body having a diameter that is substantially the same as the diameter of the third sub-magnetic body; and
the first through sixth sub-magnetic bodies are connected to first through sixth power sources, respectively.

19. The substrate processing apparatus of claim 14, wherein the first magnetic body is connected to a frequency filter that controls noise.

20. A substrate processing apparatus comprising:
a chamber configured to process a substrate;
a first electrode configured to form plasma in an internal space of the chamber;
a second electrode facing the first electrode and configured to form plasma in the internal space of the chamber;
a first magnetic body to control the plasma formed in the internal space of the chamber and located inside the chamber, the first magnetic body including:
a first magnetic field generator including a coil formed by stacking turns of a first wire, the first wire having two ends;
a first electrode structure, which is formed by both ends of the first wire; and
a first mimic structure attached to the first magnetic field generator and being spaced apart from the first electrode structure; and
a second magnetic body located opposite the first magnetic body, the second magnetic body including:
a second magnetic field generator including a coil formed by stacking turns of a second wire, the second wire having two ends;
a second electrode structure, which is formed by both ends of the second wire; and
a second mimic structure attached to the second magnetic field generator and being spaced apart from the second electrode structure,
wherein:
the first magnetic body has a diameter, the second magnetic body has a diameter, and the diameter of the first magnetic body is substantially the same as the diameter of the second magnetic body;
the first and second magnetic bodies receive current from first and second power sources, respectively;
the first electrode structure and the first mimic structure form an angle of about 180 degrees therebetween about a center of the first magnetic body;
the second electrode structure and the second mimic structure form an angle of about 180 degrees therebetween about a center of the second magnetic body; and
the first magnetic body is connected to a frequency filter that controls noise.
